(19) United States
(12) Patent Application Publication
(10) Pub. No.: US 2014/0362544 A1
(43) Pub. Date: Dec. 11, 2014

(54) WATCH TYPE MOBILE TERMINAL

(71) Applicant: LG ELECTRONICS INC., Seoul (KR)

(72) Inventors: Jongbeom HAN, Seoul (KR); Timothy KANG, Seoul (KR)

(73) Assignee: LG ELECTRONICS INC., Seoul (KR)

(21) Appl. No.: 14/030,555

(22) Filed: Sep. 18, 2013

(30) Foreign Application Priority Data
Jun. 11, 2013 (KR) 10-2013-0066657
Jun. 11, 2013 (KR) 10-2013-0066658

(51) Int. Cl. H05K 5/02; H05K 5/00

(52) U.S. Cl. CPC H05K 5/0217; H05K 5/0026
USPC 361/749; 361/748

(57) ABSTRACT

There is disclosed a watch type mobile terminal including a case comprising a front surface in which a display is mounted, and a first connecting hole connected to the mounting space in which a main board is mounted; a connector comprising a connecting passage having one end inserted in the first connecting hole, penetrating from the end and the other end; a strap comprising an inner space and a second connecting hole connected to the inner space, with one end hingedly coupled to the other end of the connector; and a flexible circuit board extended from the mounting space of the case to the inner space of the strap via the connecting passage, with one end connected to the main board, wherein a connected state between the second connecting hole and the connecting passage is maintained when the hinged coupling is rotated.

Pursuant to 35 U.S.C. §119(a), this application claims the benefit of earlier filing date and right of priority to Korean Application No. 10-2013-0066657, filed on Jun. 11, 2013 and No. 10-2013-0066658, filed on Jun. 11, 2013, the contents of which are hereby incorporated by reference herein in their entirety.

### BACKGROUND OF THE DISCLOSURE

1. Field of the Disclosure

The present invention relates to a watch type mobile terminal that is wearable on a human wrist or arm.

2. Discussion of the Related Art

There exists conventional mobile terminals that can be hand carried and has one or more functions such as voice and video call communication, inputting and outputting information, storing data, and the like.

As such functions become more diversified, the mobile terminal can support more complicated functions such as capturing images or video, reproducing music or video files, playing games, receiving broadcast signals, and the like. By comprehensively and collectively implementing such functions, the mobile terminal may be embodied in the form of a multimedia player or device.

In order to implement various functions, numerous attempts are being made in terms of hardware or software. For example, a user interface is provided to allow users to easily and conveniently search for and select one or more functions.

Also, as users consider their mobile terminal to be a personal portable device, various designs may be applied for mobile terminals to express personality of users.

Conventional mobile terminals are sized to be held in hand, so users carry around their mobile terminal in a hand-held manner or carry around their mobile terminal in pockets, purses or belt clips. However, conventional handheld mobile terminals can easily be lost or inadvertently dropped while being carried around. Watch type mobile terminals that can be put on like a wristwatch have been proposed.

Such a watch type mobile terminal is a mobile terminal that can be put on a user's wrist and sized smaller than a conventional mobile terminal. Accordingly, the watch type mobile terminal is under weight and design restrictions. The watch type mobile terminal has a disadvantage that there is an insufficient space where elements are mounted to realize various functions and it is necessary to utilize the decreased space efficiently.

Elements can be mounted in a strap and the element mounting space can be expanded. However, the strap is electrically connected with a case to exchange a signal, such that the structure between a case and a strap is hard enough to deteriorate a wearing comfort. Structural improvement is required.

### SUMMARY OF THE DISCLOSURE

An object of the present invention is to provide a watch type mobile terminal having a physically rotatable connection structure between a strap and a case, with a stable electrical link state.

To achieve these objects and other advantages and in accordance with the purpose of the invention, as embodied and broadly described herein, a watch type mobile terminal includes a case comprising a mounting space in which a display is mounted, and a first connecting hole connected to the mounting space; a connector comprising one end inserted in the first connecting hole and a connecting passage, penetrating from one end and the other portion; a strap comprising an inner space and a second connecting hole connected to the inner space, with one end hingedly coupled to the other portion of the connector; and a flexible circuit board extended from the mounting space of the case to the inner space of the strap via the connecting passage, with one end connected to the main board, wherein a connected state between the second connecting hole and the connecting passage is maintained while the connector and the strap are rotated.

A shape of the second connecting hole may be corresponding to a shape of the other end of the connector, and the other end of the connector may be inserted in the second connecting hole.

The watch type mobile terminal may further include a pair of hinge pins penetrating right and left sides of the end of the strap to couple to right and left sides of the other end of the connector, respectively.

The hinge pins may be coupled to the strap, the connector and the case simultaneously.

The other end of the connector may include a curved surface uniformly distant from a rotary axis.

The other end of the connector may be formed in a circular cylinder shape, with the curved surface extended 180 degrees or more, and the second connecting hole may be smaller than a diameter of the circular cylinder formed in the other end of the connector.

The watch type mobile terminal may further include an angle restricting end formed in a circumference of the first connecting hole of the case to restrict a rotation angle range of the strap.

The flexible circuit board may be wound around the second connecting hole once.

The other end of the connecting passage may be curved.

The watch type mobile terminal may further include a waterproof member disposed between the first connecting hole of the case and the predetermined end of the connector.

The watch type mobile terminal may further include a ring-shaped waterproof groove formed in an outer circumference of the connector; and a band-shaped waterproof ring provided between the first connecting hole of the case and the waterproof groove.

The watch type mobile terminal may further include an antenna mounted in the inner space of the strap, connected with the other end of the flexible circuit board.

In another aspect, a watch type mobile terminal includes a case comprising an mounting space in which a main board and a first connecting hole connected with the mounting space; a connector comprising one end inserted in the first connecting hole to be connected to the main board and the other portion in which a curved connecting terminal is provided; a strap comprising one end hingedly coupled to the case; and a connecting member comprising a curved surface coupled to the end of the strap to contact with the connecting terminal, the connecting member formed of a conductive material.

The connector may further include an elastic member configured to get short toward one end of the connector when a force is applied to the connecting terminal and to restitute toward the other end of the connector when the force is removed.

The connector may include a connecting pad provided in the end thereof, electrically connected to the main board, and the elastic member may include a conductive material and the elastic member is arranged between the connecting terminal and the connecting pad to electrically connect the connecting terminal and the connecting pad with each other.

The connector comprises a hole formed in the other end thereof and the connecting terminal may be a metallic ball provided in the connector, having a diameter larger than a diameter of the hole, the metallic ball partially exposed through the hole.

The connecting terminal may be a pin having a curved end.

The watch type mobile terminal may further include a hollow provided in the connector and include a closed end and the other open end, wherein the end of the hollow may further include a connecting pad electrically connected to the main board.

The watch type mobile terminal may further include a flexible circuit board disposed between the connecting terminal and the connecting pad.

The connecting terminal may be a leaf spring comprising a curved end to be exposed outside the connector.

The other end of the leaf spring may be extended to the inside of the case, and the other end of the leaf spring and the other end of the connector may be sealed by epoxy.

The connecting member may include a curved surface uniformly distant from a rotary axis of the hinge coupling.

The watch type mobile terminal may further include a waterproof member disposed between the first connecting hole of the case and one end of the connector.

The connector may further include a ring-shaped waterproof groove formed in an outer circumference thereof, and the waterproof member may be a band-shaped waterproof ring inserted in the waterproof groove.

The watch type mobile terminal may further include an antenna mounted in the inner space of the strap, connected to the connecting member.

According to at least one embodiment of the present invention, the connected portion between the strap and the case provided in the watch type mobile terminal may be rotatable. When put on by the user, the watch type mobile terminal can be transformed according to the shape of the user's arm and the wearing sensation may be enhanced.

Furthermore, the electrical connection can be maintained even while the strap and the case are rotated. The rotation of the strap and the case may not affect the functions of the component mounted in the watch type mobile terminal.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram of a watch type mobile terminal according to one embodiment of the present invention;

FIG. 2 is a perspective diagram of the watch type mobile terminal according to the embodiment of the present invention;

FIG. 3 is an exploded perspective diagram of a strap provided in the watch type mobile terminal according to the embodiment of the present invention;

FIG. 4 is a horizontal sectional diagram of the watch type mobile terminal according to the embodiment of the present invention;

FIGS. 5 and 6 are longitudinal diagrams of the watch type mobile terminal according to the embodiment of the present invention;

FIG. 7 is a perspective diagram of a watch type mobile terminal according to another embodiment of the present invention;

FIG. 8 is a horizontal sectional diagram of a strap provided in the watch type mobile terminal according to the embodiment of FIG. 7;

FIG. 9 is a sectional diagram of one embodiment of a connector provided in the watch type mobile terminal according to the embodiment of FIG. 7;

FIG. 10 is a sectional diagram of another embodiment of the connector provided in the watch type mobile terminal according to the embodiment of FIG. 7; and

FIG. 11 is a sectional diagram of a further embodiment of the connector provided in the watch type mobile terminal according to the embodiment of FIG. 7.

### DESCRIPTION OF SPECIFIC EMBODIMENTS

In the following detailed description, reference is made to the accompanying drawing figures which form a part hereof, and which show by way of illustration various embodiments.

As used herein, the suffixes ‘module’, ‘unit’ and ‘part’ are used for elements in order to facilitate the disclosure only. Therefore, significant meanings or roles are not given to the suffixes themselves and it is understood that the ‘module’, ‘unit’ and ‘part’ can be used together or interchangeably.

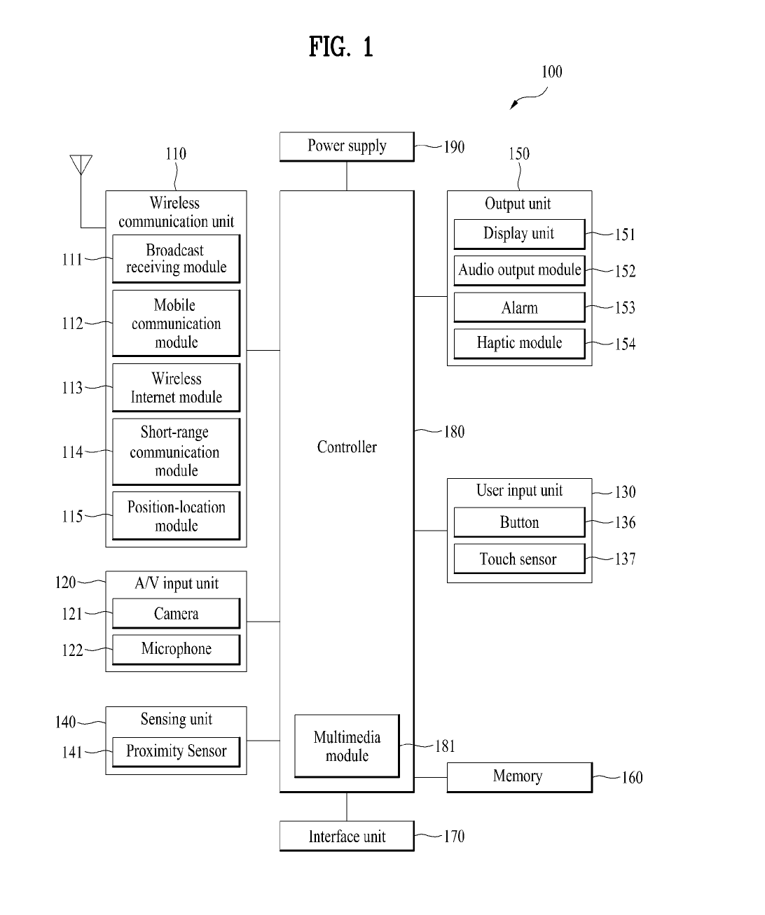

FIG. 1 is a block diagram of a watch type mobile terminal 100 in accordance with an embodiment as broadly described herein. The watch type mobile terminal 100 may include a wireless communication unit 110, an A/V (audio/video) input unit 120, a user input unit 130, a sensing unit 140, an output unit 150, a memory 160, an interface unit 170, a controller 180, a power supply unit 190 and the like. FIG. 1 shows the watch type mobile terminal 100 having various components, but it is understood that implementing all of the illustrated components is not a requirement. Greater or fewer components may alternatively be implemented.

In the following description, the above elements of the watch type mobile terminal 100 are explained in sequence.

First of all, the wireless communication unit 110 typically includes one or more components which permits wireless communication between the watch type mobile terminal 100 and a wireless communication system or network within which the watch type mobile terminal 100 is located. For instance, the wireless communication unit 110 can include a broadcast receiving module 111, a mobile communication module 112, a wireless internet module 113, a short-range communication module 114, a position-location module 115 and the like.

The broadcast receiving module 111 receives a broadcast signal and/or broadcast associated information from an external broadcast managing server via a broadcast channel. The broadcast channel may include a satellite channel and a terrestrial channel. At least two broadcast receiving modules 111 can be provided to the watch type mobile terminal 100 in pursuit of simultaneous receptions of at least two broadcast channels or broadcast channel switching facilitation.

The broadcast signal and/or broadcast associated information received by the broadcast receiving module 111 may be stored in a suitable device, such as a memory 160.

The mobile communication module 112 transmits/receives wireless signals to/from one or more network entities (e.g., base station, external terminal, server, etc.) via a mobile network such as GSM (Global System for Mobile communications), CDMA (Code Division Multiple Access), and WCDMA (Wideband CDMA) and so on. Such wireless signals may represent audio, video, and data according to text/multimedia message transmission and reception, among others.

The wireless internet module 113 supports Internet access for the watch type mobile terminal 100. This module may be internally or externally coupled to the watch type mobile terminal 100. In this case, the wireless Internet technology can include WLAN (Wireless LAN) (Wi-Fi), Wibro (Wireless broadband), Wimax (World Interoperability for Microwave Access), HSDPA (High Speed Downlink Packet Access), GSM, CDMA, WCDMA, LTE (Long Term Evolution) etc.

The short-range communication module 114 facilitates relatively short-range communications. Suitable technologies for implementing this module include radio frequency identification (RFID), infrared data association (IrDA), ultra-wideband (UWB), as well at the networking technologies commonly referred to as Bluetooth and ZigBee, to name a few.

The position-location module 115 identifies or otherwise obtains the location of the watch type mobile terminal 100. If desired, this module may be implemented with a global positioning system (GPS) module. According to the current technology, the GPS module 115 is able to precisely calculate current 3-dimensional position information based on at least one of longitude, latitude and altitude and direction (or orientation) by calculating distance information and precise time information from at least three satellites and then applying triangulation to the calculated information. Currently, location and time information are calculated using three satellites, and errors of the calculated location position and time information are then amended using another satellite. Besides, the GPS module 115 is able to calculate speed information by continuously calculating a real-time current location.

Referring to FIG. 1, the audio/video (A/V) input unit 120 may be configured to provide audio or video signal input to the watch type mobile terminal 100. As shown, the A/V input unit 120 includes a camera 121 and a microphone 122. The camera 121 receives and processes image frames of still pictures or video, which are obtained by an image sensor in a video call mode or a photographing mode. In addition, the processed image frames can be displayed on the display 151 of the output unit 150.

The image frames processed by the camera 121 can be stored in the memory 160 or can be externally transmitted via the wireless communication unit 110. Optionally, at least two cameras 121 can be provided to the watch type mobile terminal 100 according to environment of usage.

The microphone 122 receives an external audio signal while the portable device is in a particular mode, such as phone call mode, recording mode and voice recognition. This audio signal is processed and converted into electric audio data. The processed audio data is transformed into a format transmittable to a mobile communication base station via the mobile communication module 112 in case of a call mode. The microphone 122 may include assorted noise removing algorithms to remove noise generated in the course of receiving the external audio signal.

The user input unit 130 may generate input data responsive to user manipulation of an associated input device or devices. Examples of such devices include a button 136 provided to front/rear/lateral side of the watch type mobile terminal 100 and a touch sensor (pressure sensitive touch/capacitive touch) 137 and may further include a key pad, a dome switch, a jog wheel, a jog switch and the like.

The sensing unit 140 may provide sensing signals for controlling operations of the watch type mobile terminal 100 using status measurements of various aspects of the watch type mobile terminal 100. For instance, the sensing unit 140 may detect an open/close status of the watch type mobile terminal 100, relative positioning of components (e.g., a display and keypad) of the watch type mobile terminal 100, a change of position of the watch type mobile terminal 100 or a component of the watch type mobile terminal 100, a presence or absence of user contact with the watch type mobile terminal 100, orientation or acceleration/deceleration of the watch type mobile terminal 100. By nonlimiting example, such a sensing unit 140 may include, a gyro sensor, an acceleration sensor, a geomagnetic sensor and the like.

The output unit 150 may generate outputs relevant to the senses of sight, hearing, touch and the like. The output unit 150 includes the display 151, an audio output module 152, an alarm unit 153, and a haptic module 154 and the like.

The display 151 may be implemented to visually display (output) information associated with the watch type mobile terminal 100. For instance, if the watch type mobile terminal is operating in a phone call mode, the display may provide a user interface (UI) or graphical user interface (GUI) which includes information associated with placing, conducting, and terminating a phone call. As another example, if the watch type mobile terminal 100 is in a video call mode or a photographing mode, the display 151 may additionally or alternatively display images which are associated with these modes, the UI or the GUI.

The display 151 may be implemented using known display technologies including, for example, a liquid crystal display (LCD), a thin film transistor-liquid crystal display (TFT-LCD), an organic light-emitting diode display (OLED), a flexible display and a three-dimensional display. The watch type mobile terminal 100 may include one or more of such displays.

In case that the display 151 and the touch sensor 137 configures a mutual layer structure (hereinafter called ‘touch screen’), it is able to use the display 151 as an input device as well as an output device. In this case, the touch sensor may be configured as a touch film, a touch sheet, a touchpad or the like.

The touch sensor 137 can be configured to convert a pressure applied to a specific portion of the display 151 or a variation of a capacitance generated from a specific portion of the display 151 to an electric input signal. Moreover, it is able to configure the touch sensor 137 to detect a pressure of a touch as well as a touched position or size.

If a touch input is made to the touch sensor 137, signal(s) corresponding to the touch is transferred to a touch controller. The touch controller processes the signal(s) and then transfers the processed signal(s) to the controller 180. Therefore, the controller 180 is able to know whether a prescribed portion of the display 151 is touched.

A proximity sensor 141 can be provided to an internal area of the watch type mobile terminal 100 enclosed by the touchscreen or around the touchscreen. The proximity sensor 141 is the sensor that detects a presence or non-presence of an object approaching a prescribed detecting surface or an object existing around the proximity sensor using an electromagnetic field strength or infrared ray without mechanical contact. Hence, the proximity sensor has durability longer than that of a contact type sensor and also has utility wider than that of the contact type sensor.

The audio output module 152 functions in various modes including a call-receiving mode, a call-placing mode, a recording mode, a voice recognition mode, a broadcast reception mode and the like to output audio data which is received from the wireless communication unit 110 or is stored in the memory 160. During operation, the audio output module 152 outputs audio relating to a particular function (e.g., call received, message received, etc.). The audio output module 152 is often implemented using one or more speakers, buzzers, other audio producing devices, and combinations thereof.

The alarm unit 153 is output a signal for announcing the occurrence of a particular event associated with the watch type mobile terminal 100. Typical events include a call received event, a message received event and a touch input received event. The alarm unit 153 is able to output a signal for announcing the event occurrence by way of vibration as well as video or audio signal. The video or audio signal can be output via the display 151 or the audio output unit 152. Hence, the display 151 or the audio output module 152 can be regarded as a part of the alarm unit 153.

The haptic module 154 generates various tactile effects that can be sensed by a user. Vibration is a representative one of the tactile effects generated by the haptic module 154. Strength and pattern of the vibration generated by the haptic module 154 are controllable. For instance, different vibrations can be output in a manner of being synthesized together or can be output in sequence.

The haptic module 154 is able to generate various tactile effects as well as the vibration. For instance, the haptic module 154 generates the effect attributed to the arrangement of pins vertically moving against a contact skin surface, the effect attributed to the injection/suction power of air though an injection/suction hole, the effect attributed to the skim over a skin surface, the effect attributed to the contact with electrode, the effect attributed to the electrostatic force, the effect attributed to the representation of hold/cold sense using an endothermic or exothermic device and the like.

The haptic module 154 can be implemented to enable a user to sense the tactile effect through a muscle sense of finger, arm or the like as well as to transfer the tactile effect through a direct contact. Optionally, at least two haptic modules 154 can be provided to the watch type mobile terminal 100 in accordance with the corresponding configuration type of the watch type mobile terminal 100.

The memory unit 160 is generally used to store various types of data to support the processing, control, and storage requirements of the watch type mobile terminal 100. Examples of such data include program instructions for applications operating on the watch type mobile terminal 100, contact data, phonebook data, messages, audio, still pictures (or photo), moving pictures, etc. In addition, a recent use history or a cumulative use frequency of each data (e.g., use frequency for each phonebook, each message or each multimedia) can be stored in the memory unit 160. Moreover, data for various patterns of vibration and/or sound output in case of a touch input to the touchscreen can be stored in the memory unit 160.

The interface unit 170 is often implemented to couple the watch type mobile terminal 100 with external devices. The interface unit 170 receives data from the external devices or is supplied with the power and then transfers the data or power to the respective elements of the watch type mobile terminal 100 or enables data within the watch type mobile terminal 100 to be transferred to the external devices.

The interface unit 170 may be configured using a wired/wireless headset port, an external charger port, a wired/wireless data port, a memory card port, a port for coupling to a device having an identity module, audio input/output ports, video input/output ports, an earphone port and/or the like.

The identity module is the chip for storing various kinds of information for authenticating a use authority of the watch type mobile terminal 100 and can include User Identify Module (UIM), Subscriber Identify Module (SIM), Universal Subscriber Identity Module (USIM) and/or the like. A device having the identity module (hereinafter called ‘identity device’) can be manufactured as a smart card. Therefore, the identity device is connectible to the watch type mobile terminal 100 via the corresponding port.

When the watch type mobile terminal 100 is connected to an external cradle, the interface unit 170 becomes a passage for supplying the watch type mobile terminal 100 with a power from the cradle or a passage for delivering various command signals input from the cradle by a user to the watch type mobile terminal 100. Each of the various command signals input from the cradle or the power can operate as a signal enabling the watch type mobile terminal 100 to recognize that it is correctly loaded in the cradle.

The controller 180 may control the overall operations of the watch type mobile terminal 100. For example, the controller 180 may performs the control and processing associated with voice calls, data communications, video calls, etc. The controller 180 may include a multimedia module 181 that provides multimedia playback. The multimedia module 181 may be configured as part of the controller 180, or implemented as a separate component.

Moreover, the controller 180 is able to perform a pattern (or image) recognizing process for recognizing a writing input and a picture drawing input carried out on the touchscreen as characters or images, respectively.

The power supply unit 190 provides power required by the various components for the watch type mobile terminal 100. The power may be internal power, external power, or combinations thereof.

A battery may include a built-in rechargeable battery and may be detachably attached to the terminal body for a charging and the like. A connecting port may be configured as one example of the interface 170 via which an external charger for supplying a power of a battery charging is electrically connected.

Various embodiments described herein may be implemented in a computer-readable medium using, for example, computer software, hardware, or some combination thereof.

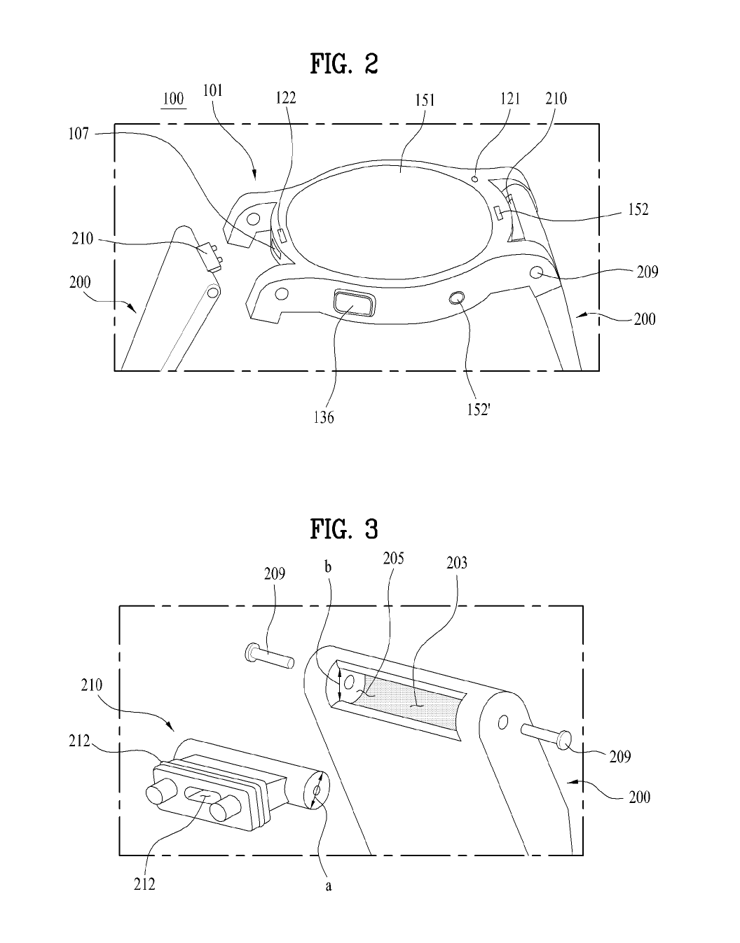

FIG. 2 is a perspective diagram of a watch type mobile terminal 100 according to one embodiment of the present invention.

As shown in FIG. 2, the watch type mobile terminal 100 may include a terminal case 101 arranged, with the display 151 exposed to an upper surface thereof. Both ends of the terminal case 101 are connected with straps 200 to allow the terminal put on the wrist or arm by the user. The terminal case 101 may include an mounting space 104 in which the wireless communication unit 110, the memory 160, a main circuit board 185 as the controller 180, and the power supply unit 190 and other devices for various additional functions.

The display 151 is mounted in the front surface of the terminal case 101 and the circuit board as the controller, a battery as the power supply unit 190, the storage 170, various sensors 140 and the like may be mounted in the terminal case 101. In addition, a card loading portion may be provided in the terminal case to detachably load a memory card, a USIM/SIM card and the like therein.

The terminal case 101 includes a plurality of cases 103 and 105 to define an exterior appearance of the terminal. As shown in FIG. 2, the terminal case may include a front case 103, a rear case 105 and a window for covering a front surface of the display 151. In the drawing, the cases 103 and 105 are circular and the shape of the cases can include a rectangular shape. Also, a cover may be further provided in a back surface of the rear case 105 to open a close the battery loading unit or the card loading portion, and a terminal may be provided in the battery loading portion or the card loading portion for electrical link with the battery or the card.

The front case 103 has an opening formed therein to arrange the display 151 therein and the window is coupled to the portion where the display 151 is arranged. The window is visibly transparent. There may be arranged in one end of the display in the window the audio output module 152 configured to output a sound and the camera 121 configured to photograph.

The display 151 may include a liquid crystal display (LCD), an organic light emitting diodes (OLED) module, an e-paper and the like. The display 151 may further include a touchpad to implement input in a touch manner. When there is a touch input at any spot on the window, contents corresponding to the touched point may be input and the contents input in the touch manner may be characters or numbers and a menu list that can be indicated or designated in various modes. A structure configured to enhance visibility of the display 151 in a bright place may be provided in an upper portion of the display 151.

The audio output module 152 may be called as a receiver in terms of outputting a received sound. The audio output module 152 may be formed in a loud speaker to provide a relatively loud sound such as outputting an alarm sound of a system, a speaker phone mode or a play mode of a multimedia.

It is difficult for users to hear sounds, with holding the watch type mobile terminal at his or her ear. The watch type mobile terminal may further include an earphone jack 152′ to output sounds via an earphone or a headset. Alternatively, the watch type mobile terminal may output sounds in manners of transmitting an audio signal to a wireless earphone via a short range communication module such as Bluetooth. In this instance, the audio output module 152 provided in the mobile terminal can be omitted.

The camera 121 is configured to take a photograph or shoot a video of a subject. When making video calls, the camera 121 may be used as a device for getting an image of the user.

A side button 136 may be arranged in a lateral surface of the case 101 and the side button 136 may be called as an operation unit and allow a command for controlling the operations of the watch type mobile terminal 100 input there through. The side button 136 may use a tactile manner in which uses operate by using a tactile sensation or a manner using a touch sensor.

Contents input via the side button 136 may be set diversely. For instance, power ON/OFF, control of the camera 121, volume control of the sounds output from the audio output module 152, conversion of the display 151 into a touch recognition module or the like.

The strap 200 may connect the both ends of the terminal case 101 to allow the watch type mobile terminal be wearable on a human body part such as a wrist or an arm. The strap 200 may be formed a flexible material that can be flexibly transformed according to the shape of the body part, for example, the wrist. Examples of such a flexible material may include leather, rubber and plastics. Or, the strap 200 may consist of segmented frames coupled by a hinge.

The strap 200 may include a fastener configured to allow the terminal body 101 tightly attached to the user's wrist or arm. The fastener may be realized in a hook structure that enables buckle and sap fit or a Velcro type. Such the strap 200 may include a flexible period or material.

The watch type mobile terminal 100 is size restricted and it is not easy to mount all of the various components mentioned above in the watch type mobile terminal 100. Especially, components subject to electromagnetic waves of peripheral electronic equipment such as an antenna 207 have to be spaced apart a predetermined distance from the other components, such that it is difficult to mount the watch type mobile terminal 100 including all of the components in the terminal case 101.

To solve the disadvantage of insufficient space for mounting the components, the antenna 207 may be mounted in one end of the strap 200. Disadvantages of receiving sensitivity deterioration and exterior appearance deterioration, which can be generated in case the antenna 207 is mounted in the terminal case 101, can be effectively solved and the component mounting space in the watch type mobile terminal 100 can be expanded. At this time, to electrically connect the antenna 207 mounted in the strap 200 with a main printed board 185 of the case 101, there has been typically used a method of connecting the strap 200 to the case 101, with no changing the shape of the strap 200.

The conventional watch type mobile terminal 100 includes the strap 100 immovable with respect to the case 101 and the strap 100 cannot be transformed, fitted to the user's wrist. There is a disadvantage of deteriorated wearing sensation.

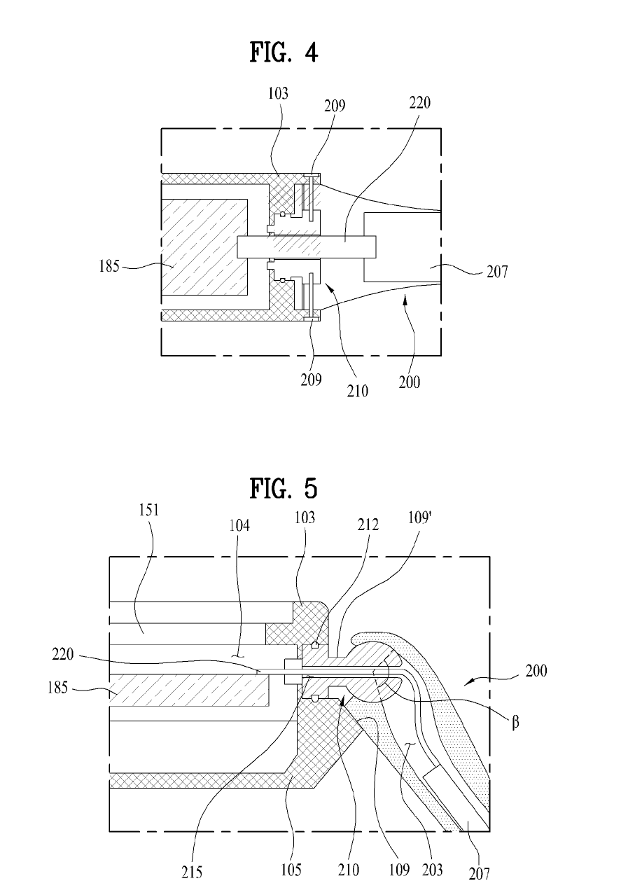

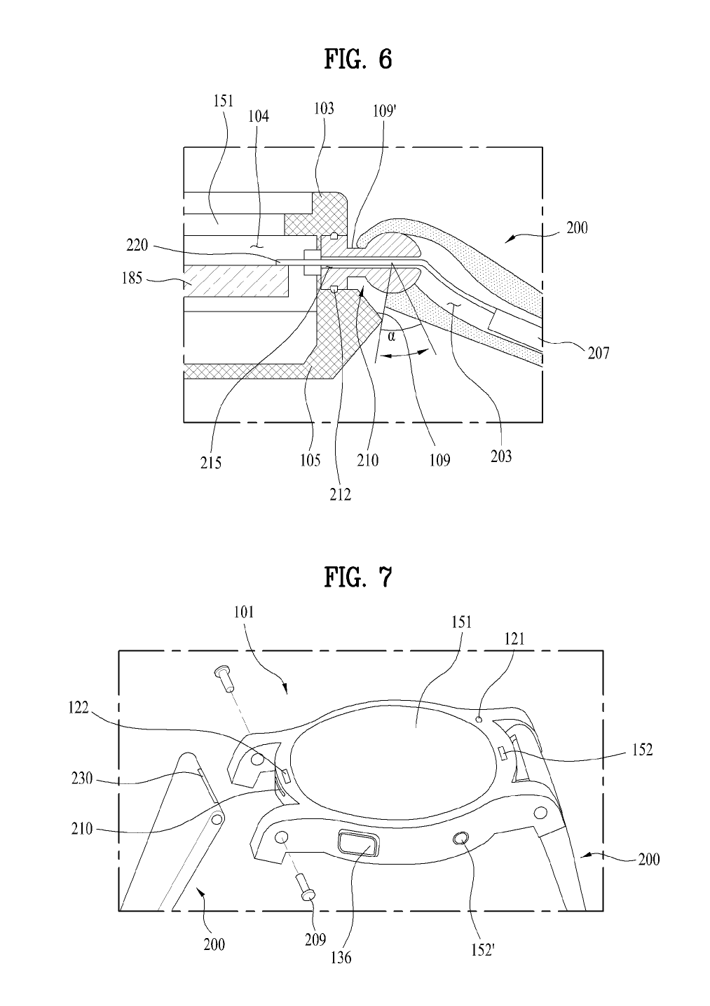

According to the embodiments of the present invention, the trap 200 is rotatably coupled to the terminal case 101 and the electrical connection between the case 101 and the strap 200 is maintained. FIG. 3 is an exploded perspective diagram of a strap provided in the watch type mobile terminal according to the embodiment of the present invention. FIG. 4 is a horizontal sectional diagram of the watch type mobile terminal according to the embodiment of the present invention. FIGS. 5 and 6 are longitudinal diagrams of the watch type mobile terminal according to the embodiment of the present invention.

The strap 200 according to the embodiment is connected with the case 101 via a connector 210. One end of the connector 210 is inserted in the case 101 and the other end is coupled to the strap 200.

The case 101 includes a first connecting hole 107 in which one end of the connector 210 can be inserted and the first connecting hole 107 is connected to the mounting space 104 mounted in the case 101. The connector 210 includes a connecting passage 215 having one end of inserted in the first connecting hole 107 and the other end penetrating the other end.

The other end of the connector 210 is hingedly coupled to the end of the strap 200. The connector 210 and the strap 200 may perform rotation on a rotary axis. A second connecting hole 205 connected with the connecting passage 215 of the connector is formed in one end of the strap 200. The inner space formed in the strap 200 is exposed via the second connecting hole 205 and electronic components such as the antenna 207 may be mounted in the inner space 203.

The other end of the connector 210 may be inserted in the second connecting hole 205. At this time, an inner shape of the second connecting hole 205 may be corresponding to the shape of the other end of the connector 210. As shown in FIG. 3, the inner shape of the second connecting hole 205 may have a curved surface along a curved surface formed in the other end of the connector 201.

As shown in FIG. 4, the other end of the connector 210 may be inserted in the second connecting hole 205 and a hinge pine 209 may be inserted in each of right/left sides of the connector 210, only to hingedly coupled the connector 210 and the strap 200 with each other. At this time, the hinge pin 209 may penetrate the case 201 as well, such that it may couple the case 201, the connector 210 and the strap 200 with each other simultaneously.

For a natural rotation of the connector 210 and the strap 200, the other end of the connector 210 may include a curved surface as large as the distance from the rotary axis as shown in FIG. 3.in other words, the other end of the connector 210 is formed in a circular cylinder shape arranged in a lateral direction and a seating groove 205 may include a curved surface corresponding to the curved surface formed in the other end of the connector 210. At this time, the curved surface formed in the other end of the connector 210 may be large by 180° or more, to secure a rotation range of the strap 200.

As shown in FIG. 4, the second connecting hole 205 is connected with the other end of the connecting passage 215, such that the inner space 203 and the mounting space 104 of the 101 may be connected with each other via the connecting passage 205. The antenna 207 mounted in the inner space 203 may be connected with the main board 185 mounted in the case 101 via a flexible circuit board 220 penetrating the second connecting hole 205, the connecting passage 215 and the first connecting hole 107.

FIG. 5 illustrates that the strap 200 is rotated at the maximum degree in a clockwise direction and FIG. 6 illustrates the strap 200 is rotated at the maximum degree in a counterclockwise direction. During the hinged-coupled rotation, the connection between the second connecting hole 205 and the connecting passage 215 are kept.

To keep the connected state between the second connecting hole 205 and the connecting passage 215, the size of the second connecting hole 205 can cover a rotation angel (α) of the rotation. In other words, an angle (β) of the second connecting hole 205 from the rotary axis may larger than the rotary axis of the second connecting hole 205. Accordingly, even while the strap 200 is rotating, the connected state between the connecting passage 215 and the second connecting hole 205 can be maintained.

If the size of the other end of the connecting passage 215 is too large, the connecting passage 215 could be exposed outside during the rotation. Accordingly, the other end of the connecting passage 215 may be relatively small and the second connecting hole 205 may be sufficiently large.

When the strap 200 is rotated, the flexible circuit board 220 might be damaged in the other end of the connecting passage 215 by the friction. When the strap 200 is wound around one end of the flexible circuit board 220 once to prevent the damage, a winding state of the flexible circuit board 220 when the strap 200 is rotated is changed and the change according to a rotation angle can be absorbed. In other words, sufficient angular variation is generated at one end of the flexible circuit board 220 and the damage to the flexible circuit board 220 can be prevented.

Alternatively, as shown in FIG. 5, the other end of the connecting passage 215 is curved such that a corner of the other end of the connecting passage 215 may prevent the damage to the flexible circuit board 220.

As shown in FIGS. 5 and 6, the rotation angle is restricted when the strap 200 contacts with the case 101 or the connector 210. Unless the rotation angle of the strap 200 is restricted, the connected state between the connecting passage 215 and the second connecting hole 205 cannot be maintained disadvantageously. The rotation angle of the strap 200 may be restricted.

As shown in FIG. 5, an angle restricting portion 109 formed in a circumference of the first connecting hole 107 formed in the case 101 may contact with the strap 200 when the strap 200 is rotated a predetermined angle, only to restrict the rotation of the strap 200 to the predetermined angle.

The angle restricting portion 109 may be projected from the case 101. Rather than the angle restricting portion 109, an angle restricting portion 109′ provided in the connector 210 as shown in FIG. 6 may contact an end of the strap 200 and restrict the rotation of the strap 200 to the predetermined angle.

As shown in FIG. 4, the strap 200 and the connector 210 may be coupled to each other by the hinge pins 209 inserted in both sides. When an entrance (a) of the second connecting hole 205 formed in the strap 200 is smaller than the other end (b) of the connector 210, without the hinge pin 209, the connector 210 will not come out and it can be rotated on this rotary axis in a state of being inserted in the second connecting hole 205.

Meanwhile, a waterproof member may be disposed between the first connecting hole 107 and the connector 210 to prevent foreign substances including moisture from permeating between the first connecting hole 107 and the connector 210. In this embodiment, a waterproof groove 212′ may be formed along a circumference of one end of the connector and a waterproof ring 212 formed of a band-shaped elastic material such as rubber and silicon may be fitted to the waterproof groove 212′ accordingly, the gap between the first connecting hole 107 and the connector 210 may be sealed airtight.

FIG. 7 is a perspective diagram of a watch type mobile terminal 100 according to another embodiment of the present invention.

As shown in FIG. 7, the watch type mobile terminal 100 according to this embodiment a terminal case 101 and a strap 200 provided in each end of the terminal case 101, similar to the embodiment shown in FIGS. 2 to 6. Compared with the embodiment mentioned above, repeated description of this embodiment is omitted.

Even in the watch type mobile terminal 100 according to this embodiment, an antenna is mounted in one end of the strap 200 so as to solve the disadvantage of the insufficient mounting space for the components.

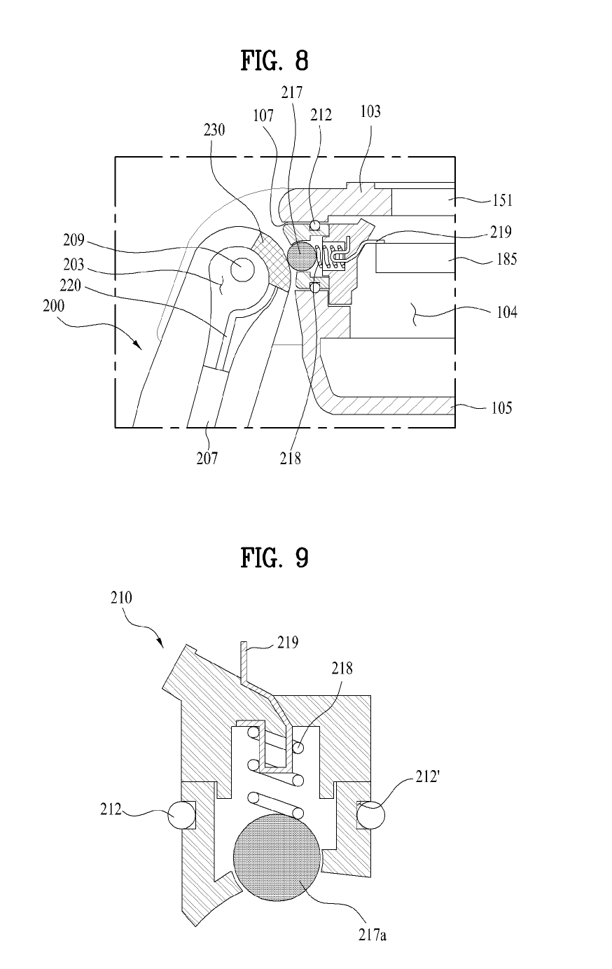

According to the embodiments of the present invention, the trap 200 is rotatably coupled to the terminal case 101 and the electrical connection between the case 101 and the strap 200 is maintained. FIG. 8 is a horizontal sectional diagram of a strap provided in the watch type mobile terminal according to the embodiment of FIG. 7. FIG. 9 is a sectional diagram of the connector shown in FIG. 8.

The strap 200 according to this embodiment includes an inner space 203 in which electronic components are mounted. The electronic components such as the antenna 207 may be mounted in the inner space 203. A connecting member 230 may be provided in an end of the strap 200 and the connecting member 230 is formed of a conductive material, to electrically connect the antenna 207 to the case 101 of the watch type mobile terminal 100. A flexible circuit board 220 may be provided for electrical connection between the connecting member 230 and the antenna 207.

The connecting member 230 may include a curved surface to maintain the electrical connection with the case 101, when the strap 200 hingedly coupled to the case 101 is rotated. In case a distance from a rotary axis of the hinged coupling forms a predetermined curvature, the distance between the surface of the connecting member 230 and the case 101 can be maintained uniformly even during the rotation of the strap 200.

One end of the strap 200 according to this embodiment may be rotatably coupled to the case 101 by a hinge and electrically connected to the case 101 via a connector 210. As shown in FIG. 7, a hinge pin 209 may insertedly penetrate the case 101 and inserted in right and left sides of the strap 200, to hingedly couple the case 101 and the strap 200 to each other.

The case 101 includes a first connecting hole 107 in which an end of the connector 210 can be inserted and the first connecting hole 107 is connected to an mounting space 104 provided in the case 101.

An end of the connector 210 is inserted in the first connecting hole 107 and one end of the connector 210 is electrically connected to the main board 185 mounted in the mounting space 104. The connector 210 may include a connecting pad 219 formed of a metallic material may be provided in an end of the connector 210 to be connected to the main board 185. As shown in FIG. 8, the connecting pad 219 may be projected from the end of the connector 210 to be directly coupled to the main board 185.

A connecting terminal 217 is arranged in the other end of the connector 210 and the connecting terminal 217 can be electrically connected to the strap 200. The connecting terminal has a curved surface to prevent cut-off of the electrical connection with the strap 200, when the strap 200 is rotated. In this embodiment, the connecting terminal 217 may be a metallic ball 217a and a hole formed in one end of the connector 210 is smaller than the metallic ball 217a, such that the metallic ball 217a may not be separated from the connector 210.

The connecting terminal 217 and the connecting pad 219 are electrically connected with each other. In case the connecting member 230 has a curved surface having an uniform distance from a rotary axis, the distance between the surface of the connecting member 230 and the connecting terminal 217 may not be changed and the connect with the connecting terminal 217 can be maintained.

However, when an external shock is applied or the user applies a strong force, the distance between the surface of the connecting member 230 and the connecting terminal 217 could be changed minutely. An elastic member may be further provided to maintain the connection state even in this instance. The elastic member may be positioned between the connecting pad 219 and the connecting terminal 217 to absorb the force applied to the connecting terminal 217 and to restitute the connecting terminal 217. At this time, when a spring 218 as the elastic member is formed of a conductive material the spring can also perform electrical connection between the connecting terminal 217 and the connecting pad 219.

Meanwhile, a waterproof member may be disposed between the first connecting hole 107 and the connector 210 to prevent foreign substances including moisture from permeating between the first connecting hole 107 and the connector 210. In this embodiment, a waterproof groove 212′ may be formed along a circumference of one end of the connector and a waterproof ring 212 formed of a band-shaped elastic material such as rubber and silicon may be fitted to the waterproof groove 212′ accordingly, the gap between the first connecting hole 107 and the connector 210 may be sealed airtight.

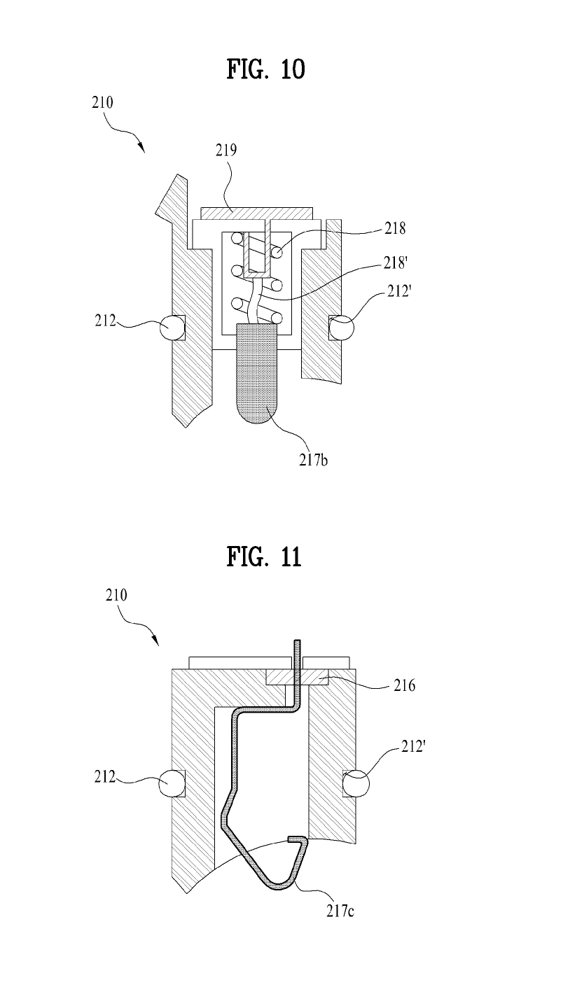

FIG. 10 is a diagram of another embodiment of the connector 210. Different from the embodiment of the connector shown in FIG. 9, a metallic pin 217b of which an end is a curved surface may be provided instead of the metallic ball 217a. The metallic pin 217b has the curved surface, like the metallic ball 217a, only to maintain the contact with the connecting member 230 of the strap 200. Here, the metallic ball 217a can be rotated together with the strap 200, when the strap 200 is rotated. The metallic pin 217b cannot be rotated and only moved forward and backward (vibration movement) from one end of the connector 210 only toward the other end by the elasticity of the spring 218.

In this embodiment, a flexible circuit board 218′ may be used for electrical connection between the connecting terminal 217 and the connecting pad 219. In case the spring is not formed of a conductive material, only having the elasticity with respect to the force applied to the connecting terminal 217, the flexible circuit board may be disposed. Such the flexible circuit board may be flexibly transformed, corresponding to the movement of the connecting terminal 217. Accordingly, even if the length of the spring is changed, the flexible circuit board may not be damaged.

FIG. 11 is a sectional diagram of a further embodiment of the connector 210 provided in the watch type mobile terminal 100.

In this embodiment, the connecting terminal 217 includes a leaf spring 217c. Such a leaf spring 217c can use the elasticity of a metallic plate that will return to its original shape and metal is a conductive material. Accordingly, direct electrical connection can be performed by the leaf spring 217c.

As shown in FIG. 11, an end of the leaf spring 217c to form a curved surface such that the connecting terminal 217 having a curved cross section can be realized. As the connecting terminal 217 has the elasticity, the spring 218 and the connecting pad 219 can be omitted and the leaf spring 217c may be extended to an end of the connector 210, to be directly connected to the main board 185.

To form the leaf spring 217c, one member is inserted in the connector 210. A waterproof material such as an epoxy 216 is provided to waterproof-seal between the leaf spring 217c and a housing of the connector 210.

According to at least one embodiment of the present invention, the connected portion between the strap 200 and the case 101 provided in the watch type mobile terminal may be rotatable. When put on by the user, the watch type mobile terminal 100 can be transformed according to the shape of the user's arm and the wearing sensation may be enhanced.

Furthermore, the electrical connection can be maintained even while the strap 200 and the case 101 are rotated. The rotation of the strap 200 and the case 101 may not affect the functions of the component mounted in the watch type mobile terminal 100.

Although embodiments have been described with reference to a number of illustrative embodiments thereof, it should be understood that numerous other modifications and embodiments can be devised by those skilled in the art that will fall within the spirit and scope of the principles of this disclosure.

More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A watch type mobile terminal comprising:
a case comprising a mounting space in which a main board is mounted and a first connecting hole connected to the mounting space;
a connector comprising one end inserted in the first connecting hole and a connecting passage penetrating from one end and the other end of the connector;
a strap comprising an inner space and a second connecting hole connected to the inner space, with one end hingedly coupled to the other end of the connector; and
a flexible circuit board extended from the mounting space of the case to the inner space of the strap via the connecting passage, with one end connected to the main board,
wherein a connected state between the second connecting hole and the connecting passage is maintained while the connector and the strap are rotated.

2. The watch type mobile terminal according to claim 1, wherein a shape of the second connecting hole is corresponding to a shape of the other end of the connector, and
the other end of the connector is inserted in the second connecting hole.

3. The watch type mobile terminal according to claim 2, further comprising:
a pair of hinge pins penetrating right and left sides of the end of the strap to couple to right and left sides of the other end of the connector, respectively.

4. The watch type mobile terminal according to claim 3, wherein the hinge pins are coupled to the strap, the connector and the case simultaneously.

5. The watch type mobile terminal according to claim 2, wherein the other end of the connector comprises a curved surface uniformly distant from a rotary axis.

6. The watch type mobile terminal according to claim 5, wherein the other end of the connector is formed in a circular cylinder shape, with the curved surface extended 180 degrees or more, and
the second connecting hole is smaller than a diameter of the circular cylinder formed in the other end of the connector.

7. The watch type mobile terminal according to claim 1, further comprising:
an angle restricting portion formed in the connector or a circumference of the first connecting hole of the case to restrict a rotation angle range of the strap.

8. The watch type mobile terminal according to claim 1, wherein the flexible circuit board is wound around the second connecting hole once.

9. The watch type mobile terminal according to claim 1, wherein the other end of the connecting passage is curved.

10. The watch type mobile terminal according to claim 1, further comprising:
a ring-shaped waterproof groove formed in an outer circumference of the connector; and
a band-shaped waterproof ring provided between the first connecting hole of the case and the waterproof groove.

11. The watch type mobile terminal according to claim 1, further comprising:
an antenna mounted in the inner space of the strap, connected with the other end of the flexible circuit board.

12. A watch type mobile terminal comprising:
a case comprising an mounting space in which a main board is mounted and a first connecting hole connected to the mounting space;
a connector comprising one end inserted in the first connecting hole to be connected to the main board and the other end in which a curved connecting terminal is provided;
a strap comprising one end hingedly coupled to the case; and
a connecting member having a curved surface and coupled to the end of the strap to contact with the connecting terminal, the connecting member formed of a conductive material.

13. The watch type mobile terminal according to claim 12, wherein the connector further comprises,
an elastic member configured to get short toward one end of the connector when a force is applied to the connecting terminal and to restitute toward the other end of the connector when the force is removed.

14. The watch type mobile terminal according to claim 13, wherein the connector comprises a connecting pad provided in one end thereof, electrically connected to the main board, and
the elastic member comprises a conductive material and the elastic member is arranged between the connecting terminal and the connecting pad to electrically connect the connecting terminal and the connecting pad with each other.

15. The watch type mobile terminal according to claim 13, wherein the connecting terminal is a spherical metallic ball provided in the connector in a state of being partially exposed via a hole formed in the other end of the connector, with a diameter larger than the hole, or a metallic pin having a curved end.

16. The watch type mobile terminal according to claim 13, further comprising:
a hollow provided in the connector, comprising a closed end and the other open end,
wherein the end of the hollow further comprises a connecting pad electrically connected to the main board.

17. The watch type mobile terminal according to claim 16, further comprising:
a flexible circuit board disposed between the connecting terminal and the connecting pad.

18. The watch type mobile terminal according to claim 12, wherein the connecting terminal is a leaf spring comprising a curved end to be exposed outside the connector.

19. The watch type mobile terminal according to claim 19, wherein the other end of the leaf spring is extended to the inside of the case, and
the other end of the leaf spring and the other end of the connector are sealed by epoxy.

20. The watch type mobile terminal according to claim 12, wherein the connecting member comprises a curved surface uniformly distant from a rotary axis of the hinge coupling.
